(19) United States
(12) Patent Application Publication
(10) Pub. No.: US 2003/0128519 A1
(43) Pub. Date: Jul. 10, 2003

(54) Flexible, thermally conductive, electrically insulating gap filler, method to prepare same, and method using same

(75) Inventors: Roger Javier Justo, Tucson, AZ (US); Wayne Alan McKinley, Tucson, AZ (US); Hussain Shaukatullah, Tucson, AZ (US); George G. Zamora, Vail, AZ (US)

Correspondence Address: Dale F. Regelman, Hayes, Soloway, Hennessey,, Grossman & Hage, P.C., 130 W. Cushing Street, Tucson, AZ, 85701, US

(73) Assignee: International Business Machine Corporartion

(21) Appl. No.: 10/041,111

(22) Filed: Jan. 8, 2002

(51) Int. Cl. H05K 7/20; B32B 7/12; B32B 15/04

(52) U.S. Cl. 361/704; 428/343

(57) ABSTRACT

A flexible, thermally conductive, electrically insulating, non-contaminating, assembly formed from a thermally conductive elastomeric member encapsulated within an electrically insulating coating. A method to form Applicants' thermally conductive, electrically insulating, non-contaminating assembly. An electrical device that includes Applicants' thermally conductive, electrically insulating, non-contaminating assembly disposed between one or more heat-dissipating electrical components and a chassis. A method to transfer heat from one or more heat-dissipating electrical components disposed within a device.

### FIELD OF THE INVENTION

Applicants' invention relates to a flexible, thermally conductive, electrically insulating, non-contaminating, encapsulated assembly. Applicants' invention further relates to method to form Applicants' flexible, thermally conductive, electrically insulating assembly. Applicants' invention further relates to an electrical device which includes Applicants' flexible, thermally conductive, electrically insulating assembly disposed between one or more heat-dissipating electrical components and a chassis. Applicants' invention further relates to a method to transfer heat from one or more heat dissipating components disposed within an electrical device, or other heat dissipating devices.

### BACKGROUND OF THE INVENTION

Circuit density and power dissipation of integrated circuits comprising a plurality of components packaged in a single device are increasing. In addition, these heat-generating devices are housed in smaller and smaller packages resulting in increased power dissipation from a relatively small volume. Frequently due to package size constraints, there is insufficient space to install cooling fans in electronic devices comprising such integrated circuits.

Magnetic tape drive units and optical disk/floppy disk/hard disk drive units include heat-generating electronic components in combination with a number of high-precision moving parts, such as read/write heads, that are positioned in close proximity to moving data storage media. These moving parts are very susceptible to contamination. Therefore, components and materials used in such drive units must be free from contaminants, including solids, semi-solids, and liquids. In addition, such components and/or materials cannot release liquids and/or vapors that could contaminate moving parts, magnetic or optical media, and read/write heads, or that could form a coating on moving parts, and thereby, facilitate the accumulation of dust and debris.

What is needed is an apparatus to conduct heat from heat-generating components using a flexible, thermally conductive, electrically insulating, non-contaminating assembly. Such a flexible, thermally conductive, electrically insulating, non-contaminating assembly must function well in any orientation. In addition, such an assembly must be flexible and soft in order to conform to mechanical tolerances, prevent mechanical damage due to stresses caused by shipping/handling, and minimize damage resulting from differential thermal expansion during operation.

### SUMMARY OF THE INVENTION

Applicants' invention includes thermally conductive assembly formed from a flexible, thermally conductive elastomer encapsulated with an electrically insulating coating. The coating prevents release from Applicants' thermally conductive assembly of one or more substances emitted by the elastomeric member. Such one or more released substances can comprise one or more substances that are solid at room temperature, one or more substances that are semisolid at room temperature, one or more substances that are gases at room temperature, and mixtures thereof.

Prior to encapsulation, the thermally conductive elastomer is treated to remove low molecular weight compounds that could be emitted under actual use conditions. Unlike prior art devices, Applicants' assembly remains flexible at low temperatures, is electrically insulating, will not cause electrical shorting pathways between components disposed on a circuit substrate, is insensitive to orientation, will not result in immediate or complete loss of cooling due to accidental puncture, and minimizes contamination in the event of an accidental puncture.

Applicants' invention includes a method to form Applicants' flexible thermally conductive assembly. Applicants' invention further includes an electrical device which includes Applicants' flexible thermally conductive assembly disposed between one or more heat-dissipating components and a chassis. Applicants' invention further includes a method to transfer heat from one or more heat-dissipating components disposed within an electrical device.

### BRIEF DESCRIPTION OF THE DRAWINGS

The invention will be better understood from a reading of the following detailed description taken in conjunction with the drawings in which like reference designators are used to designate like elements, and in which:

FIG. 1 is a cross sectional view of a first embodiment of Applicants' flexible thermally conductive assembly;

FIG. 1A is a cross sectional view of one embodiment of an elastomeric thermally conductive elastomeric member used to form Applicants' flexible thermally conductive assembly;

FIG. 2 is a cross sectional view of a second embodiment of Applicants' flexible thermally conductive assembly;

FIG. 3 is a cross sectional view of a third embodiment of Applicants' flexible thermally conductive assembly

FIG. 4 is a cross sectional view of a fourth embodiment of Applicants' flexible thermally conductive assembly;

FIG. 5 is a cross sectional view of a fifth embodiment of Applicants' flexible thermally conductive assembly;

FIG. 6 is a flowchart summarizing Applicants' method to form their flexible thermally conductive assembly;

FIG. 7 is a cross-sectional view of an electrical device which includes three heat-dissipating electrical components disposed on a first circuit substrate, a chassis, and Applicants' flexible thermally conductive assembly disposed between those electrical components and the chassis;

FIG. 8 is a cross-sectional view of an electrical device which includes three heat-dissipating electrical components disposed on a second circuit substrate, a chassis, and Applicants' flexible thermally conductive assembly disposed between those electrical components and the chassis;

FIG. 9 is a cross-sectional view of a tape drive unit/optical disk drive unit/floppy disk drive unit which includes three heat-dissipating electrical components disposed on a circuit substrate, a chassis, and Applicants' flexible thermally conductive assembly disposed between those electrical components and the chassis;

FIG. 10 is a cross-sectional view of a hard disk drive unit which includes three heat-dissipating electrical components disposed on a circuit substrate, a chassis, and Applicants' flexible thermally conductive assembly disposed between those electrical components and the chassis; and

FIG. 11 is a flowchart summarizing Applicants' method to transfer heat to a chassis from one or more heat-dissipating electrical components disposed within an electrical device.

### DETAILED DESCRIPTION OF THE PREFERRED EMBODIMENTS

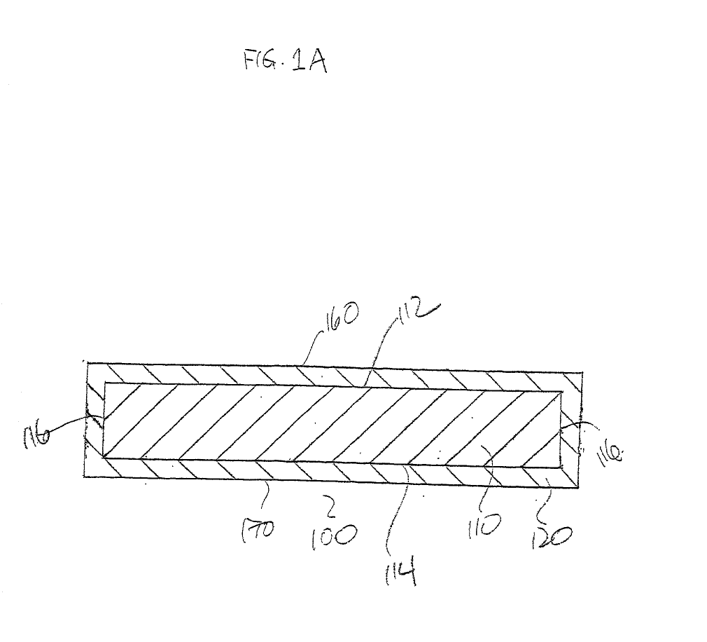

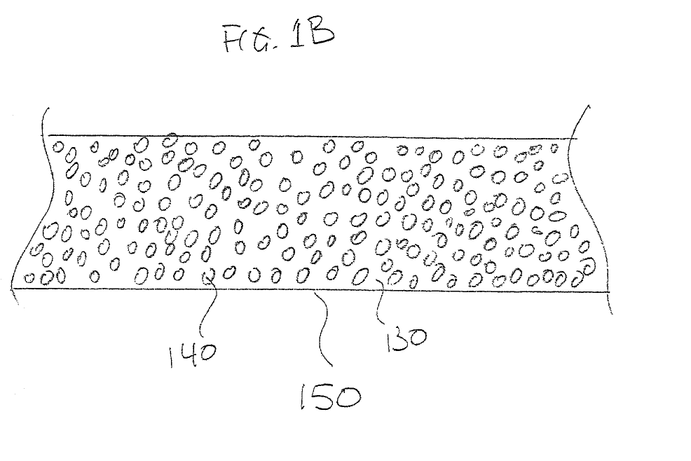

Referring to FIG. 1, flexible thermally conductive assembly 100 is shown including thermally conductive, elastomeric member 110 encapsulated within coating 120. Assembly 100 includes first surface 160 and second surface 170.

By elastomeric, Applicants mean member 110 has a Shore A hardness, determined using Method ASTM 2240 promulgated by the American Society for Testing and Materials (“ASTM”), of between about SA and about 95A. In certain embodiments, Applicant's invention includes an elastomeric member having a hardness less than about 5A, or more than about 95A. As those skilled in the art will appreciate, the hardness testing of plastics, including synthetic elastomers, is most commonly measured by the Shore (Durometer) test or Rockwell hardness test. Both methods measure the resistance of the plastic toward indentation. Shore Hardness, using either the Shore A or Shore D scale, is the preferred method for rubbers/elastomers and is also commonly used for “softer” plastics such as polyolefins, fluoropolymers, and vinyls. The Shore A scale is used for “softer” rubbers while the Shore D scale is used for “harder” ones.

The Shore hardness is measured with an apparatus known as a Durometer and consequently is also known as “Durometer hardness.” The hardness value is determined by the penetration of the Durometer indenter foot into the sample. The ASTM test number is ASTM D2240 while the analogous ISO test method is ISO 868.

By thermally conductive, Applicants mean a material having a thermal conductivity of greater than 0 Watts per meter degree Kelvin (W/m K). As those skilled in the art will appreciate, the thermal conductivity, λ, is the quantity of heat transmitted, due to unit temperature gradient, in unit time under steady conditions in a direction normal to a surface of unit area, when the heat transfer is dependent only on the temperature gradient. See, D. R. Lide, (Ed.), Chemical Rubber Company Handbook of Chemistry and Physics, CRC Press, Boca Raton, Fla., USA, 79th edition, 1998.

In certain embodiments, member 110 has a thermal conductivity λ of about 0.025 W/m K. In other embodiments, member 110 has a thermal conductivity λ equal to or greater than about 1.0 W/m K. In yet other embodiments, member 110 has a thermal conductivity λ equal to or greater than about 2.0 W/m K.

In the embodiment shown in FIG. 1B, thermally conductive elastomeric member 110 (FIG. 1A) comprises multi-phase structure 150 wherein continuous phase 130 comprises one or more polymeric material(s), and discontinuous phase 140 includes one or more additive(s). As those skilled in the art will appreciate, the sizes of the individual discontinuous components 140 shown in FIG. 1A are exaggerated with respect to the size of member 110 for illustrative purposes. In general, these discontinuous components 140 are not individually discernable without the use of magnification.

In certain embodiments, continuous phase 130 comprises a crosslinked polydialkylsiloxane. In certain embodiments, member 110 comprises a “gel” material in combination with one or more thermally conductive solids. In these embodiments, discontinuous phase 140 comprises both a solvent component in tight combination with a polymeric continuous phase 130 and one or more solid materials, such as alumina or silica, colloidally suspended in that polymer/solvent gel.

In certain embodiments, continuous phase 130 comprises a cellular structure which includes open cells and/or closed cells and/or combinations thereof. As those skilled in the art will appreciate, the cellular embodiments of continuous phase 130 have lesser densities than do their non-cellular analogs.

In certain embodiments, discontinuous phase 140 includes one or more solids, one or more semi-solids, one or more liquids, and combinations thereof. By solids, Applicants mean materials having both a volume and a shape that are invariant at room temperature. By liquids, Applicants mean materials having a volume, but not a shape, that is invariant at room temperature. By semi-solids, Applicants mean components that include both solids and liquids.

In certain embodiments, discontinuous phase 140 includes alumina, silica, beryllium oxide, copper, aluminum, silver, gold, diamond, boron nitride, polytetrafluoroethylene, and combinations thereof. In certain embodiments, discontinuous phase 140 includes one or more linear polydialkylsiloxanes, such as polydimethylsiloxane, of varying molecular weights.

Referring again to FIG. 1A, thermally conductive elastomeric member 110 includes first side 112 and opposing second side 114 joined by a plurality of edges 116. In certain embodiments, member 110 has a thickness of between about 0.5 mm and about 5 cm. In certain embodiments, member 110 is between about 3 mm and about 5 mm. Applicants' invention includes devices wherein member 110 has a thickness less than about 0.5 mm, and devices wherein member 110 has a thickness greater than about 5 mm.

The length and width of member 110 can vary over large ranges. In certain embodiments, the length of member 110 is between about 0.5 cm and about 50 cm in length. In certain embodiments, the width of member 110 is between about 0.5 cm and about 50 cm in width. Other widths and lengths to meet specific applications are possible and acceptable.

In certain embodiments, member 110 is formed from products sold by The Bergquist Company (Gap Pad VO™ and Gap Pad VO Soft™), 5300 Edina Industrial Blvd., Minneapolis, Minn. 55439; Fujipoly (SARCON®), 365 Carnegie Avenue, Kenilworth, N.J. 07033; Parker Seals/CHOMERICS (Therma-A-Gap™), 77 Dragon Court, Woburn, Mass., 01888; and Kersamische Folien Gmbh (KERATHERM®), Stegenthumbach 4-6, D-92676 Eschenbach i.d. Opf., Germany.

Applicants have found, however, that these commercially-available materials suffer from a common problem, namely, release of contaminants in actual use. Such contaminants include, for example, one or more silicone oils. In order to minimize the unwanted release of such contaminants, Applicants' invention includes encapsulating thermally conductive member 110 in coating 120. Coating 120 prevents the migration of materials released by thermally conductive member 110. Such released materials include gaseous materials, liquid materials, solid materials, semi-solid materials, and combinations thereof.

In certain embodiments, coating 120 is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polypropylene terephthalate, polybutylene terephthalate, polynaphthalene terephthalate, polyvinylacetate, polyamide, polyimide, polyamideimide, polyurethane, polyvinyl fluoride, polyvinylidene fluoride, polyvinyl chloride, polyvinylidene chloride, and mixtures thereof. By polyethylene (“PE”) Applicants mean low density PE, linear low density PE, high density PE, ultra high molecular weight PE, and combinations thereof. In certain embodiments, coating 120 is between about 0.01 mm and about 0.1 mm in thickness. In other embodiments, coating 120 has a thickness less than about 0.01 mm. In yet other embodiments, coating 120 has a thickness greater than about 0.1 mm.

Coating 120 is an electrically-insulating material. By electrically-insulating, Applicants mean a material that has a dielectric strength of at least 100 volts/mil at a one mil thickness. As those skilled in the art will appreciate, the dielectric strength of a material comprises the maximum electric field strength that it can withstand intrinsically without breaking down, i.e., without experiencing failure of its insulating properties. ASTM Method D149, using a frequency of about 60 hertz, is typically used to determine a material's dielectric strength. In certain embodiments, coating 120 has a dielectric strength of at least 500 volts per mil, determined using Method D149. In certain embodiments, coating 120 has a dielectric strength of about 5000 volts per mil determined using Method D149. In other embodiments, coating 120 has a dielectric strength of about 7500 volts per mil determined using Method D149.

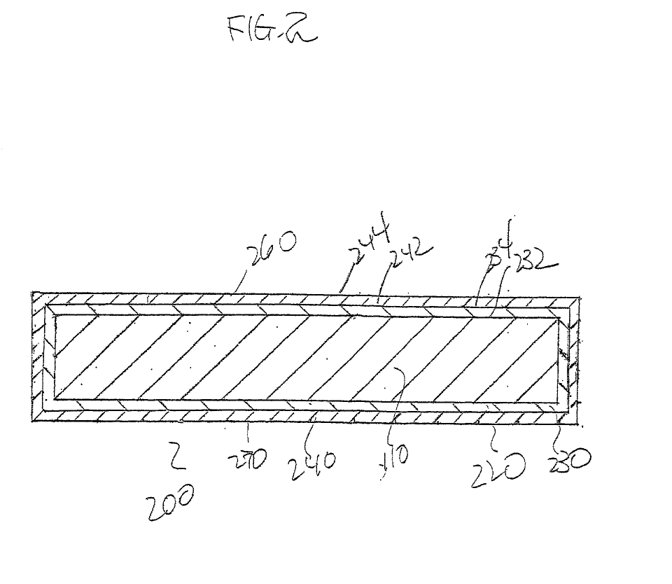

Referring now to FIG. 2, thermally conductive assembly 200 includes thermally conductive, elastomeric member 110 encapsulated by coating 220. Assembly 200 includes first surface 260 and opposing second surface 270. Coating 220 includes inner layer 230 and outer layer 240. Inner layer 230 includes first side 232 and second side 234. Outer layer 240 includes first side 242 and second side 244. In assembly 200, first side 232 of inner layer 230 is disposed adjacent thermally conductive, elastomeric member 110. Second side 234 of inner layer 230 is disposed adjacent first side 242 of outer layer 240. In assembly 200, second side 244 of outer layer 240 comprises the first surface 260 and second surface 270.

Inner layer 230 is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polyamide, polyimide, polyamideimide, polyurethane, polyvinyl fluoride, polyvinylidene fluoride, polyvinyl chloride, polyvinylidene chloride, and mixtures thereof. By polyethylene (“PE”) Applicants mean low density PE, linear low density PE, high density PE, ultra high molecular weight PE, and combinations thereof. In certain embodiments, inner layer 230 has a thickness between about 0.01 mm and about 0.5 mm. In other embodiments, inner layer 230 has a thickness less than about 0.01 mm. In yet other embodiments, inner layer 230 has a thickness greater than about 0.5 mm.

Outer layer 240 is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polyamide, polyimide, polyamideimide, polyurethane, polyvinyl fluoride, polyvinylidene fluoride, polyvinyl chloride, polyvinylidene chloride, and mixtures thereof. By polyethylene (“PE”) Applicants mean low density PE, linear low density PE, high density PE, ultra high molecular weight PE, and combinations thereof. In certain embodiments, outer layer 240 has a thickness of between about 0.01 mm and about 0.1 mm. In other embodiments, outer layer 240 has a thickness less than about 0.01 mm. In yet other embodiments, outer layer 240 has a thickness greater than about 0.1 mm.

In one embodiment, coating 220 comprises a flexible enclosure formed from a two layer laminate wherein that laminate comprises an inner layer formed from polyethylene having a thickness of about 0.05 mm, and an outer layer formed from polyethylene terephthalate having a thickness of about 0.05 mm. In certain embodiments, outer layer 240 has a greater dielectric strength layer than does either inner layer 230 and/or elastomeric member 110. In certain embodiments, inner layer 230 has a greater dielectric strength than does elastomeric member 110.

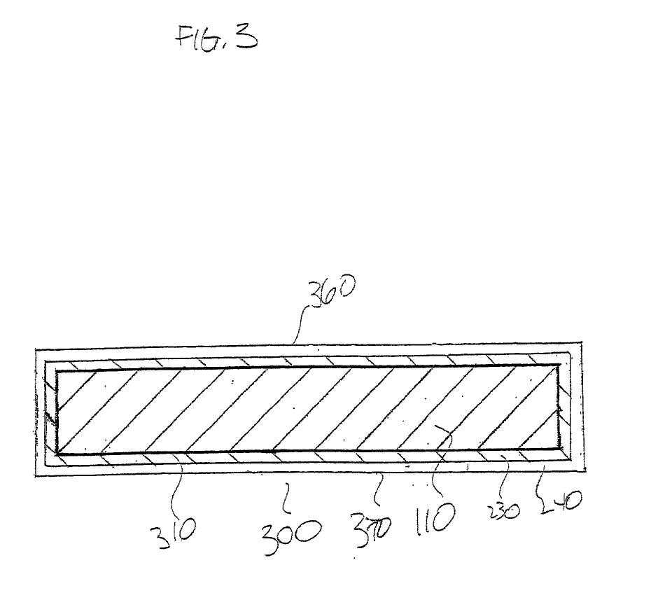

Referring to FIG. 3, thermally conductive assembly 300 includes thermally conductive elastomer 110 encapsulated by first layer 230 which is encapsulated by second layer 240. In this embodiment of Applicants' invention, metal layer 310 is disposed between the outer surface 112 of member 110 and first surface 232 of inner layer 230. Metal layer 310 comprises one or more metals selected from the group consisting of copper, aluminum, steel, gold, silver, chromium, nickel, iron, titanium, magnesium, manganese, tin, and mixtures thereof. In certain embodiments, metal layer 310 comprises aluminum. In certain embodiments, metal layer 310 has a thickness between about 0.1 μm and about 50 μm. In other embodiments, metal layer 310 has a thickness less than about 0.1 μm. In yet other embodiments, metal layer 310 has a thickness greater than about 50 μm.

In certain embodiments, Applicants' assembly includes an adhesive disposed on a first surface to facilitate installation in an electronic device. That first surface, including the adhesive, is generally installed on a metal cover or chassis. The second surface, i.e. the non-adhesive bearing surface, makes contact with one or more heat dissipating components disposed on one or more circuit substrates. This construction is advantageous because a small puncture of the coating of Applicants' assembly could result in a small release of contaminants. Such a de minimus release occurring from the first surface would be contained between the chassis and the flexible thermally conductive assembly, thereby preventing the migration of such contaminants throughout the device.

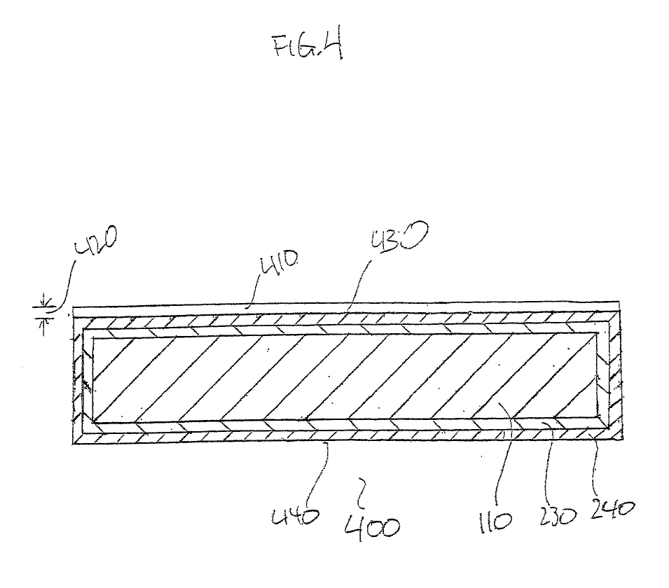

Referring now to FIG. 4, flexible thermally conductive assembly 400 includes thermally elastomeric member 110, first layer 230, second layer 240, and adhesive 410 disposed on first surface 430. Adhesive 410 has thickness 420. In certain embodiments, thickness 420 is about 0.05 mm. In other embodiments, thickness 420 is less than about 0.05 mm. In alternative embodiments, thickness 420 is greater than about 0.05 mm. In the embodiment shown in FIG. 4, second surface 440 of assembly 400 includes no adhesive.

In certain embodiments, the adhesive disposed on first surface 430 comprises a pressure sensitive adhesive. By pressure sensitive adhesive, Applicants' mean a material that imparts instantaneous adhesion at room temperature of their flexible thermally conductive assembly to a substrate, such as a chassis, using only finger-tip applied laminating pressure, where that adhesion is maintained at device operating temperatures.

First surface 430 including adhesive 410 can be conveniently installed on the inside of the chassis of an electrical device. Non-adhesive bearing surface 440 makes contact with one or more heat dissipating components disposed within that electrical device. Applicants have found it undesirable to dispose adhesive 410 on both first surface 430 and second surface 440.

Simultaneously tightly fixturing assembly 400 to one or more electrical components and to a chassis can mechanically stress those electrical components because of the differing coefficients of thermal expansion (“CTE”) exhibited by those electrical components, assembly 400, and the chassis. Such mechanical stress can lead to component damage and failure. On the other hand, disposing adhesive 410 on first surface 430 only imparts flexibility to assembly 400 such that second surface 440 can move along one or more axes to relieve stress generated by CTE mismatches. This flexibility prevents mechanical damage to heat-generating components, and hence, results in an increased mean time between failures for devices utilizing assembly 400.

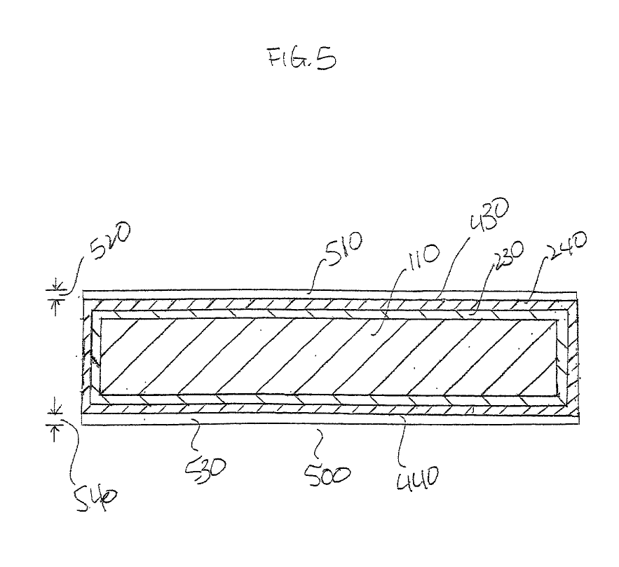

A “dry contact,” i.e. an interface between two different solids, generally exhibits high thermal resistance, i.e. decreased thermal conductivity. FIG. 5 shows embodiment 500 of Applicants' flexible thermally conductive assembly wherein coating 510 is disposed on first surface 430, and coating 530 is disposed on second surface 440. Coating 510 has thickness 520 which is generally between about 0.01 mm and about 2 mm. Coating 520 has thickness 540 which is generally between about 0.01 mm and about 2 mm.

In certain embodiments, coating 510 and/or coating 530 are formed from the group comprising a semi-solid material having a thermal conductivity X of at least 0.5 W/m K, a semi-solid material having one or more melting points below about 20° C. and one or more melting points above about 40° C., and combinations thereof. Semi-solid has the meaning recited above.

In certain embodiments, coating 510 and/or coating 530 comprises a grease having a thermal conductivity of at least 0.5 W/m K. Those skilled in the art will appreciate that a number of such greases are sold in commerce.

In certain embodiments, coating 510 and/or coating 530 comprise a material having a melting point between about 20° C. and about 100° C. In certain embodiments, coating 510 and/or coating 530 comprise a material having a melting point between about 30° C. and about 80° C. In certain embodiments, coating 510 and/or coating 530 comprise a material having a melting point between about 35° C. and about 70° C.

In certain embodiments, coating 510 and/or coating 530 comprises beeswax. In certain embodiments, coating 510 and/or coating 530 comprises a plurality of hydrocarbon compounds having structure I, with n equal to or greater than about 13 (pentadecane, mp=10° C.), and less than or equal to about 22 (tetracosane, mp=51° C.).

H₃C(CH₂)ₙCH₃ I

In certain embodiments, coating 510 and/or coating 530 comprises a product sold under the tradename THERMFLOW® made by Parker Seals/CHOMERICS.

In certain embodiments, coating 510 comprises adhesive 410 (FIG. 4) and coating 530 is formed from the group comprising a semi-solid material having a thermal conductivity λ of at least 0.5 W/m K, a semi-solid material having one or more melting points below about 20° C. and one or more melting points above about 40° C., and combinations thereof.

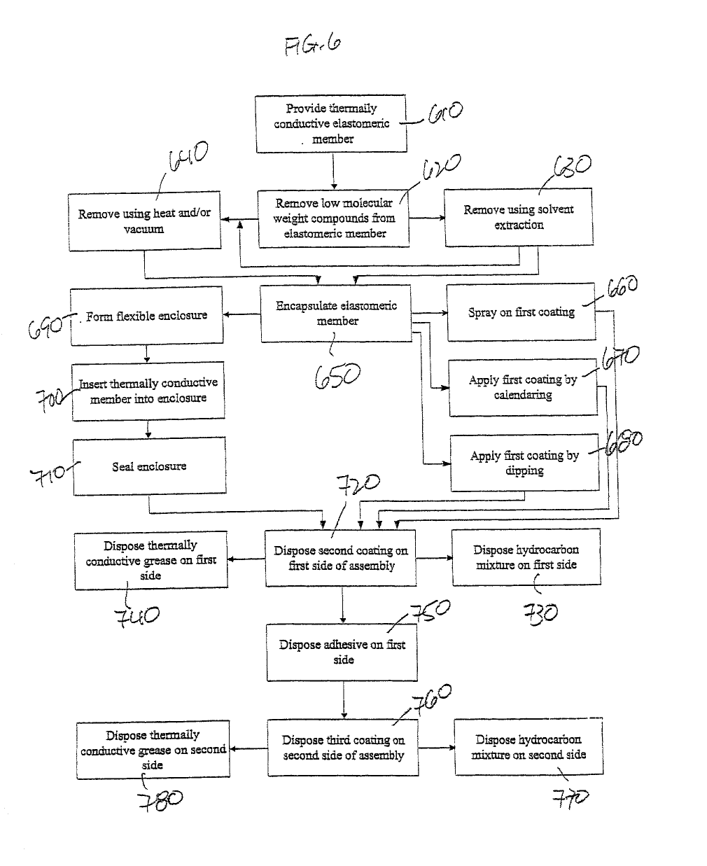

FIG. 6 summarizes the steps in Applicants' method to form flexible thermally conductive assembly 100/200/300/400/500. In step 610, a thermally conductive elastomeric material, such as member 110, is fashioned to appropriate dimensions, i.e. length, width, and thickness. In step 620 low molecular weight components are removed from that thermally conductive elastomeric material. By low molecular weight compounds, Applicants mean compounds having a molecular weight less than about 1,000 daltons.

In certain embodiments of Applicants methods, the appropriately dimensioned thermally conductive elastomeric material is solvent extracted in step 630 to remove low molecular weight components, i.e. polymerization solvents, monomers, oligomers, and the like. As those skilled in the art will appreciate, an appropriate apparatus, such as a Soxhlet apparatus, and an appropriate extraction solvent, are used.

In certain embodiments, in step 640 the appropriately dimensioned thermally conductive elastomeric material is heated at an elevated temperature at a reduced pressure to remove volatile compounds. By volatile compounds, Applicants' mean materials having a boiling point less than about 100° C. at a pressure of about 100 mm Hg. In certain embodiments, in step 640 the appropriately dimensioned thermally conductive elastomeric material is placed in a vacuum oven apparatus operated at a temperature of about 100° C., at a pressure of about 50 mm or less, for a period of about 24 hours. In certain embodiments, the appropriately dimensioned thermally conductive elastomeric material is first solvent extracted in step 630 and then heated in a vacuum in step 640.

Regardless of the step(s) used to remove low molecular weight components, the treated thermally conductive elastomeric material has a Shore A hardness of between about 5A and about 95A, and a thermal conductivity λ of at least 0.1 after steps 620/630/640.

In step 650, the treated thermally conductive elastomeric material is encapsulated with a coating, such as coating 120. In certain embodiments, coating 120 is applied using a spraying process wherein the one or more components comprising coating 120, with or without one or more solvents, are sprayed onto member 110. In the event one or more solvents are used, those solvents are removed using a vacuum oven as discussed above. In other embodiments, coating 120 is formed by spraying one or more monomers over member 110, and those one or more monomers are then polymerized using, for example, heat, ultraviolet energy, infrared energy, a radiation beam, and the like.

In certain embodiments, in step 670 the precursor to coating 120 is applied to member 110 by a calendaring process. In these embodiments coating 120 is formed by curing that precursor material using one of a number of known processes. In certain embodiments, in step 680 coating 120 is applied to member 110 by dipping member 110 into a liquid precursor to coating 120, and then curing that precursor to form coating 120 using known techniques.

In certain embodiments, coating 120 is formed in step 690 by first forming a flexible enclosure, and then in step 700 inserting treated member 110 into that flexible enclosure, and then in step 710 sealing that flexible enclosure. In certain embodiments, a flexible enclosure is formed around member 110 by, for example, placing member 110 between two sheets of material, and then sealing those two sheets together along the four edges of member 110.

In one embodiment, thermally conductive member 110 is placed between a first sheet of polymeric material, such as polyethylene, and a second sheet of polymeric material, such as polyethylene. Polyethylene has the meaning recited above. The first sheet of polymeric material is then bonded to the second sheet of polyethylene along each of the plurality of edges 116 (FIG. 1) joining first side 112 (FIG. 1) and second side 114 (FIG. 1) of member 110 to form assembly 100 (FIG. 1).

In another embodiment, thermally conductive member 110 is placed between a first and a second sheet of a two layer polyethylene/polyethylene terephthalate laminate. In this embodiment, both first side 112 and second side 114 are disposed adjacent the polyethylene portion of that two layer laminate. Polyethylene has the meaning recited above. The first sheet of laminate is then bonded to the second sheet of laminate along the edges of the thermally conductive member to form assembly 200.

In another embodiment, thermally conductive member 110 is placed between a first and a second sheet of a three layer metal/polyethylene/polyethylene terephthalate laminate. In this embodiment, both the upper and lower surfaces of member 100 contact the metal portion of the three layer laminate. Polyethylene has the meaning recited above. The first sheet of laminate is then thermally bonded to the second sheet of laminate along the four edges of the thermally conductive member to form assembly 300.

In certain embodiments, Applicants' method includes step 720 wherein a second coating is disposed on a first surface of Applicants' encapsulated thermally conductive member to form assembly 400. In certain embodiments, in step 730 a thermal wax-type material comprising a mixture of hydrocarbon compounds is disposed on a first surface of Applicants' encapsulated thermally conductive member to form assembly 400 (FIG. 4) wherein coating 410 (FIG. 4) comprises that hydrocarbon mixture. In certain embodiments, in step 740 a thermal grease is disposed on a first surface of Applicants' encapsulated thermally conductive member to form assembly 400 wherein coating 410 comprises that grease. In certain embodiments, in step 750 a pressure sensitive adhesive is disposed on a first surface of Applicants' encapsulated thermally conductive member to form assembly 400 wherein coating 410 comprises that pressure sensitive adhesive.

In certain embodiments, in step 760 a third coating is applied to a second surface of Applicants' encapsulated thermally conductive member to form assembly 500. In certain embodiments the second coating and the third coating are the same. In other embodiments, the second coating and the third coating differ.

In certain embodiments, in step 770 a thermal wax-type material comprising a mixture of hydrocarbon compounds is disposed on the second surface of Applicants' encapsulated thermally conductive member to form assembly 500 (FIG. 4) wherein coating 530 (FIG. 4) comprises that hydrocarbon mixture. In certain embodiments, in step 780 a thermally conductive grease is disposed on a second surface of Applicants' encapsulated thermally conductive member to form assembly 500 wherein coating 530 comprises that thermal grease.

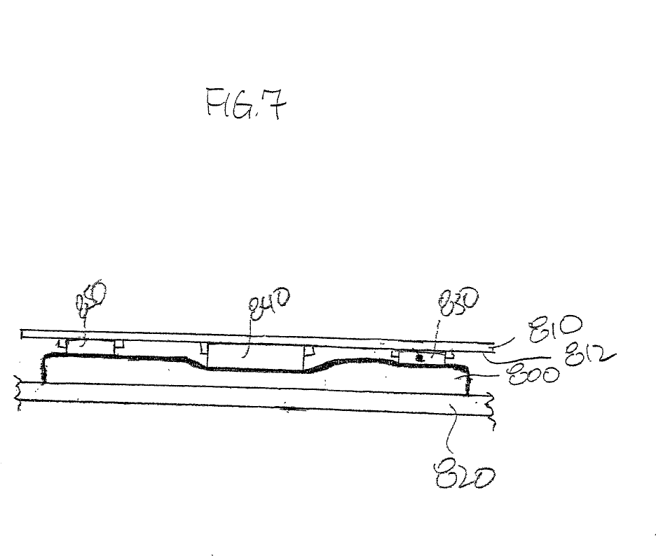

Referring now to FIG. 7, Applicants' flexible thermally conductive assembly 800 is shown disposed between chassis 820 and electrical component 830, electrical component 840, and electrical component 850. Electrical components 830, 840, and 850 are disposed first side 812 of circuit substrate 810. In certain embodiments, assembly 800 is selected from the group consisting of assembly 100 (FIG. 1), assembly 200 (FIG. 2), assembly 300 (FIG. 3), assembly 400 (FIG. 4), and assembly 500 (FIG. 5). In the embodiment shown in FIG. 7, circuit substrate 810 comprises a single-sided substrate wherein components are disposed on one side only. As those skilled in the art will appreciate, circuit substrate 810 is selected from the group comprising a fiber-reinforced plastic material, a ceramic material, silicon oxide, a ceramic-covered metal substrate, an injection molded member, and the like.

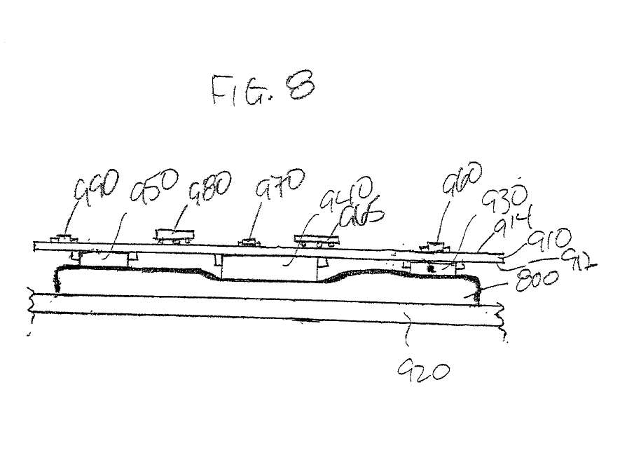

Referring now to FIG. 8, Applicants' flexible thermally conductive assembly 800 is shown disposed between chassis 920 and electrical component 930, electrical component 940, and electrical component 950. Electrical components 930, 940, and 950 are disposed on first side 912 of circuit substrate 910. Electrical components 960, 965, 970, 980, and 990, are disposed on second side 914. In certain embodiments, assembly 800 is selected from the group consisting of assembly 100 (FIG. 1), assembly 200 (FIG. 2), assembly 300 (FIG. 3), assembly 400 (FIG. 4), and assembly 500 (FIG. 5). In the embodiment shown in FIG. 8, circuit substrate 910 comprises a double-sided substrate wherein components are disposed on both sides. As those skilled in the art will appreciate, circuit substrate 910 is selected from the group comprising a fiber-reinforced plastic material, a ceramic material, silicon oxide, a ceramic-covered metal substrate, an injection molded member, and the like.

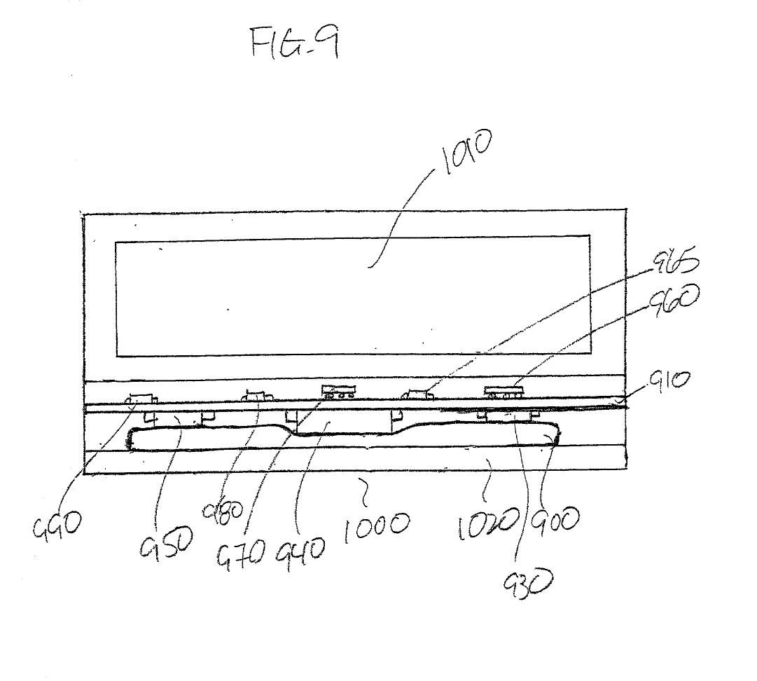

FIG. 9 shows tape drive/optical disk drive/floppy disk drive unit 1000 which includes access port 1010 and chassis 1020. Drive unit 1000 further includes Applicants' flexible thermally conductive assembly 800 disposed between chassis 1020 and electrical component 930, electrical component 940, and electrical component 950. Electrical components 930, 940, and 950 are disposed on first side 912 of circuit substrate 910. Electrical components 960, 965, 970, 980, and 990, are disposed on second side 914. In certain embodiments, assembly 800 is selected from the group consisting of assembly 100 (FIG. 1), assembly 200 (FIG. 2), assembly 300 (FIG. 3), assembly 400 (FIG. 4), and assembly 500 (FIG. 5).

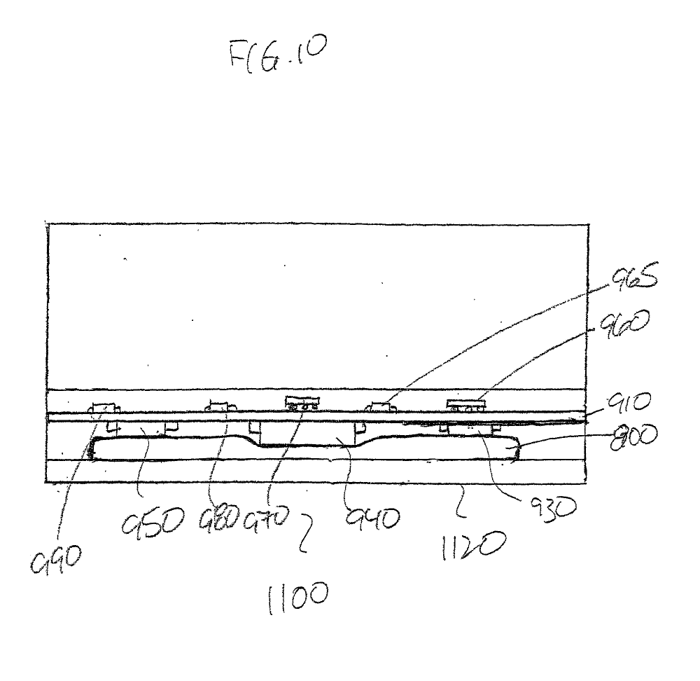

FIG. 10 shows hard disk drive unit 1100 which includes hard disk 1010 (not shown in FIG. 10) internally disposed within chassis 1020. Hard drive unit 1100 further includes Applicants' flexible thermally conductive assembly 800 disposed between chassis 1120 and electrical component 930, electrical component 940, and electrical component 950. Electrical components 930, 940, and 950 are disposed on first side 912 of circuit substrate 910. Electrical components 960, 965, 970, 980, and 990, are disposed on second side 914. In certain embodiments, assembly 800 is selected from the group consisting of assembly 100 (FIG. 1), assembly 200 (FIG. 2), assembly 300 (FIG. 3), assembly 400 (FIG. 4), and assembly 500 (FIG. 5).

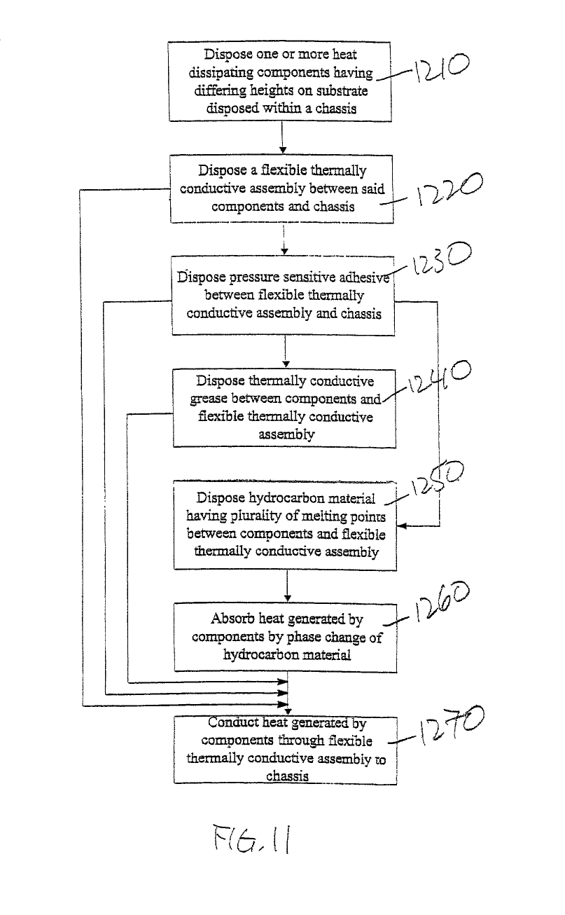

FIG. 11 is a flow chart summarizing the steps in Applicants' method to conduct heat away from one or more heat-dissipating components disposed within an electrical device. In step 1210, one or more heat dissipating components having differing heights are disposed on a circuit substrate, such as substrate 810 (FIG. 7) or substrate 910 (FIGS. 9, 10, 11), disposed within an electrical device, such as tape drive unit 1000 (FIG. 9)/optical disk drive unit 1000 (FIG. 9)/floppy disk drive unit 1000 (FIG. 9)/hard disk drive unit 1100 (FIG. 10) having a chassis, such as chassis 1020/1120.

In step 1220, an encapsulated thermally conductive member, such as assembly 100/assembly 200/assembly 300, is disposed between those one or more components and the chassis. In certain embodiments, Applicants' method then transitions to step 1270 wherein the heat dissipated by the one or more components is conducted through assembly 100/assembly 200/assembly 300 to chassis 1020/1120.

In other embodiments, Applicants' method transitions from step 1220 to step 1230 wherein assembly 400 which includes coating 410 comprising an adhesive disposed on surface 430, is disposed between the one or more components and chassis 1020/1120 as described above. In certain embodiments, Applicants' method then transitions to step 1270 wherein the heat dissipated by the one or more components is conducted through assembly 400 to chassis 1020/1120.

In other embodiments, Applicants' method transitions from step 1230 to step 1240 wherein assembly 500 which includes coating 510 comprising an adhesive disposed on surface 430 and coating 530 which comprises a thermal grease disposed on surface 440, is disposed between the one or more components and chassis 1020/1120 in the manner described above. In certain embodiments, Applicants' method then transitions to step 1270 wherein the heat dissipated by the one or more components is conducted through assembly 500 to chassis 1020/1120.

In other embodiments, Applicants' method transitions from step 1230 to step 1250 wherein assembly 500 which includes coating 510 comprising an adhesive disposed on surface 430 and coating 530 which comprises a mixture of hydrocarbon compounds having a plurality of melting points disposed on surface 440, is disposed between the one or more components and chassis 1020/1120 in the manner described above. In these embodiments, Applicants' method then transitions from step 1250 to step 1260 wherein the heat dissipated by the one or more components is partially absorbed by the crystalline components of the hydrocarbon mixture, in the amount of their respective heats of fusion. In these embodiments, Applicants' method then transitions to step 1270 wherein the heat dissipated by the one or more components is also conducted through assembly 500 to chassis 1020/1120.

While the preferred embodiments of the present invention have been illustrated in detail, it should be apparent that modifications and adaptations to those embodiments may occur to one skilled in the art without departing from the scope of the present invention as set forth in the following claims.

What is claimed is:

1. A thermally conductive assembly, comprising:
a flexible, thermally conductive elastomeric member comprising a first side, an opposing second side, and a plurality of edges connecting said first side and said second side; and
an electrically insulating first coating encapsulating said elastomeric member, wherein said first coating prevents release from said thermally conductive assembly of one or more substances emitted by said elastomeric member.

2. The thermally conductive assembly of claim 1, wherein said first coating further comprises:
an inner layer having a first side and an opposing second side;
an outer layer having a first side and an opposing second side;
wherein said first side of said inner layer is disposed adjacent said elastomeric member; and
wherein said second side of said inner layer is disposed adjacent said first side of said outer layer.

3. The thermally conductive assembly of claim 2, wherein said inner layer is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polypropylene terephthalate, polybutylene terephthalate, polynaphthalene terephthalate, polyvinylacetate, polyamide, polyimide, polyamideimide, polyurethane, polyvinyl fluoride, polyvinylidene fluoride, polyvinyl chloride, polyvinylidene chloride, and mixtures thereof.

4. The thermally conductive assembly of claim 2, wherein said outer layer is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polypropylene terephthalate, polybutylene terephthalate, polynaphthalene terephthalate, polyvinylacetate, polyamide, polyimide, polyamideimide, polyurethane, polyvinyl fluoride, polyvinylidene fluoride, polyvinyl chloride, polyvinylidene chloride, and mixtures thereof.

5. The thermally conductive assembly of claim 1, further comprising a metal layer disposed between said first side of said inner layer and said elastomeric member.

6. The thermally conductive assembly of claim 5, wherein said metal layer comprises aluminum.

7. The thermally conductive assembly of claim 1, wherein said thermally conductive assembly comprises a first surface and an opposing second surface, further comprising a semisolid material disposed on said first surface.

8. The thermally conductive assembly of claim 7, further comprising a semi-solid material disposed on said second surface.

9. The thermally conductive assembly of claim 7, further comprising a pressure sensitive adhesive disposed on said second surface.

10. The thermally conductive assembly of claim 1, wherein said thermally conductive assembly comprises a first surface and an opposing second surface, further comprising a plurality of hydrocarbons disposed on said first surface.

11. The thermally conductive assembly of claim 10, further comprising a plurality of hydrocarbons disposed on said second surface.

12. The thermally conductive assembly of claim 10, further comprising a pressure sensitive adhesive disposed on said second surface.

13. The thermally conductive assembly of claim 1, wherein said thermally conductive assembly comprises a first surface and an opposing second surface, further comprising a pressure sensitive adhesive disposed on said first surface.

14. A method to form a flexible thermally conductive assembly, comprising the steps of:
providing a flexible, thermally conductive elastomeric member comprising a first side, an opposing second side, and a plurality of edges connecting said first side and said second side;
heating said elastomeric member at a reduced pressure;
removing volatile components from said elastomeric member; and
encapsulating said elastomeric member with an electrically-insulating first coating.

15. The method of claim 14, further comprising the step of extracting said elastomeric member using a solvent.

16. The method of claim 14, wherein said disposing step further comprises the steps of:
forming a flexible enclosure;
inserting said elastomeric member into said flexible enclosure; and
sealing said flexible enclosure.

17. The method of claim 14, wherein said disposing step further comprises the steps of:
providing a first sheet of polymeric material;
providing a second sheet of polymeric material;
disposing said elastomeric member between said first sheet of polymeric material and said second sheet of polymeric material; and
bonding said first sheet of polymeric material to said second sheet of polymeric material adjacent each of said plurality of edges.

18. The method of claim 14, further comprising the step of disposing a second coating on said first coating.

19. The method of claim 18, wherein said second coating comprises a pressure sensitive adhesive.

20. The method of claim 18, further comprising the step of disposing a third coating on said first coating.

21. The method of claim 20, wherein said third coating comprises a plurality of hydrocarbons.

22. A device, comprising:
an enclosure;
a plurality of heat dissipating components disposed within said enclosure; and
a flexible thermally conductive assembly disposed between said plurality of heat dissipating electrical components and said enclosure, wherein said flexible thermally conductive assembly comprises:
a flexible, thermally conductive elastomeric member comprising a first side, an opposing second side, and a plurality of edges connecting said first side and said second side; and
an electrically-insulating first coating disposed on said elastomeric member, wherein said first coating prevents release from said thermally conductive assembly of one or more substances emitted from said elastomeric member.

23. The device of claim 22, wherein said plurality of heat dissipating electrical components have differing dimensions.

24. The device of claim 22, wherein said first coating further comprises:
an inner layer having a first side and an opposing second side;
an outer layer having a first side and an opposing second side;
wherein said first side of said inner layer is disposed adjacent said elastomeric member; and
wherein said second side of said inner layer is disposed adjacent said first side of said outer layer.

25. The device of claim 24, wherein said inner layer is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polypropylene terephthalate, polybutylene terephthalate, polynaphthalene terephthalate, polyvinylacetate, polyamide, polyimide, polyamideimide, polyurethane, polyvinyl fluoride, polyvinylidene fluoride, polyvinyl chloride, polyvinylidene chloride, and mixtures thereof.

26. The device of claim 24, wherein said outer layer is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polypropylene terephthalate, polybutylene terephthalate, polynaphthalene terephthalate, polyvinylacetate, polyamide, polyimide, polyamideimide, polyurethane, polyvinyl fluoride, polyvinylidene fluoride, polyvinyl chloride, polyvinylidene chloride, and mixtures thereof.

27. The device of claim 24, further comprising a metal layer disposed between said first side of said inner layer and said elastomeric member.

28. The device of claim 27, wherein said metal layer comprises aluminum.

29. The device of claim 22, wherein said flexible thermally conductive assembly further comprises a first surface and a second surface, further comprising a semi-solid material disposed on said first surface.

30. The device of claim 29, wherein said flexible thermally conductive assembly further comprises a semi-solid material disposed on said second surface.

31. The device of claim 29, wherein said flexible thermally conductive assembly further comprises a first surface and a second surface, further comprising a pressure sensitive adhesive disposed on said second surface.

32. The device of claim 22, wherein said flexible thermally conductive assembly further comprises a first surface and a second surface, further comprising a plurality of hydrocarbons disposed on said first surface.

33. The device of claim 32, further comprising a plurality of hydrocarbons disposed on said second surface.

34. The device of claim 32, further comprising a pressure sensitive adhesive disposed on said second surface.

35. The device of claim 32, wherein said flexible thermally conductive assembly further comprises a first surface and a second surface, further comprising a pressure sensitive adhesive disposed on said first surface.

36. A method to transfer heat from a plurality of heat-dissipating components disposed within an enclosure, comprising the steps of:
disposing a thermally conductive assembly between said plurality of heat-dissipating components and said enclosure;
conducting heat generated by said heat-dissipating components through said flexible thermally conductive assembly to said enclosure;
wherein said flexible thermally conductive assembly comprises:
a flexible thermally conductive elastomeric member comprising a first side, an opposing second side, and a plurality of edges connecting said first side and said second side; and
an electrically-insulating first coating encapsulating said elastomeric member.

37. The method of claim 36, further comprising the step of preventing release from said thermally conductive assembly of one or more substances emitted by said elastomeric member.

38. The method of claim 36, wherein said first coating further comprises:
an inner layer having a first side and an opposing second side;
an outer layer having a first side and an opposing second side;
wherein said first side of said inner layer is disposed adjacent said elastomeric member; and
wherein said second side of said inner layer is disposed adjacent said first side of said outer layer.

39. The method claim 38, wherein said inner layer is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polypropylene terephthalate, polybutylene terephthalate, polynaphthalene terephthalate, polyvinylacetate, polyamide, polyimide, polyamideimide, polyurethane, polyvinyl fluoride, polyvinylidene fluoride, polyvinyl chloride, polyvinylidene chloride, and mixtures thereof.

40. The method claim 38, wherein said outer layer is formed from the group consisting of natural rubber, polybutadiene, polyisoprene, polystyrene, polyethylene, polychlorotrifluoroethylene, polytetrafluoroethylene, perfluoroalkoxy Teflon®, ethylene/chlorotrifluoroethylene copolymer, ethylene/tetrafluoroethylene copolymer, polypropylene, polyethylene/polypropylene copolymer, fluorinated ethylene-propylene copolymer, polyethylene terephthalate, polypropylene terephthalate, polybutylene terephthalate, polynaphthalene terephthalate, polyvinylacetate, polyamide, polyimide, polyamideimide, polyurethane, polyvinyl fluoride, polyvinylidene fluoride, polyvinyl chloride, polyvinylidene chloride, and mixtures thereof.

41. The method claim 38, wherein said flexible thermally conductive assembly further comprises a metal layer disposed between said first side of said inner layer and said elastomeric member.

42. The method claim 41, wherein said metal layer comprises aluminum.

43. The method of claim 36, wherein said flexible thermally conductive assembly further comprises a first surface and a second surface, further comprising a semi-solid material disposed on said first surface.

44. The method of claim 43, further comprising a semi-solid material disposed on said second surface.

45. The method of claim 36, further comprising a pressure sensitive adhesive disposed on said second surface.

46. The method of claim 36, wherein said flexible thermally conductive assembly further comprises a first surface and a second surface, further comprising a plurality of hydrocarbons disposed on said first surface.

47. The method of claim 46, further comprising a plurality of hydrocarbons disposed on said second surface.

48. The method of claim 46, wherein said thermally conductive assembly further comprises a pressure sensitive adhesive disposed on said second surface.

49. The method of claim 36, wherein said flexible thermally conductive assembly further comprises a first surface and a second surface, further comprising a pressure sensitive adhesive disposed on said first surface.
